(19) United States
(12) Patent Application Publication
(10) Pub. No.: US 2023/0328438 A1
(43) Pub. Date: Oct. 12, 2023

(54) MULTI-CHANNEL CONVERTERS AND RECONFIGURATION THEREOF

(71) Applicant: Cirrus Logic International Semiconductor Ltd., Edinburgh (GB)

(72) Inventor: Andrew J. HOWLETT, Edinburgh (GB)

(73) Assignee: Cirrus Logic International Semiconductor Ltd., Edinburgh (GB)

(21) Appl. No.: 18/180,429

(22) Filed: Mar. 8, 2023

Related U.S. Application Data
(60) Provisional application No. 63/322,767, filed on Mar. 23, 2022.

(30) Foreign Application Priority Data
Jul. 22, 2022 (GB) 2210795.7

(51) Int. Cl. H04R 5/04; H04R 3/12

(52) U.S. Cl. CPC H04R 5/04; H04R 3/12; H04R 2499/11

(57) ABSTRACT

An audio codec integrated circuit (IC), comprising: an audio input interface; an audio output interface, wherein a first one of the audio input interface and the audio output interface comprises a plurality of interface pins, each interface pin configured to receive a respective one of a plurality of audio input signals or output a respective one of a plurality of audio output signals; a plurality of data converters for converting the plurality of audio input signals into the plurality of audio output signals; and routing circuitry for routing the plurality of audio input signals to the data converters and the plurality of audio output signals from the data converters, the routing circuitry configurable by at least one select pin to adjust the order of routing of the plurality of audio input signals to the data converters or the order of routing of the plurality of audio output signals from the data converters.

### TECHNICAL FIELD

The present disclosure relates to multi-channel converter integrated circuits, specifically reconfiguration thereof.

### BACKGROUND

Integrated circuits (ICs) comprising multiple converters (such as analog-to-digital converters (ADCs) or digital to analog converters (DACs) are well known in the art. Such ICs comprise a plurality of converters each configured to convert an input signal into a respective output signal. For audio applications, converter ICs are typically incorporated into a larger device or rack with physical ports for coupling to inputs and outputs of the converter IC. Pinouts are distributed around an edge of the IC to allow for a spaced routing of printed circuit board (PCB) traces to the ports which avoids overlap. This fixed physical orientation of both ports and routing can lead to limitations in options for reconfiguration of the device. For example, an IC mounted on the topside of a circuit board will have a different I/O configuration to the same device on the underside of the circuit board.

### SUMMARY

According to a first aspect of the disclosure, there is provided a converter integrated circuit (IC), comprising: an input interface; an output interface, wherein a first one of the input interface and the output interface comprises a plurality of interface pins, each interface pin configured to receive a respective one of a plurality of input signals or output a respective one of a plurality of output signals; a plurality of data converters for converting the plurality of input signals into the plurality of output signals; and routing circuitry for routing the plurality of input signals to the data converters and the plurality of output signals from the data converters, the routing circuitry configurable by at least one select pin to adjust the order of routing of the plurality of input signals to the data converters or the order of routing of the plurality of output signals from the data converters.

A second one different from the first one of the input interface and the output interface may comprise a digital serial interface configured to time division multiplex the plurality of output signal signals into a serial output signal or to convert a received serial input signal into the plurality of input signals.

In some embodiments, the input interface comprises the digital serial interface and the input interface is configured to receive the serial input signal.

In some embodiments, the output interface comprises the digital serial interface and the output interface is configured to output the serial output signal.

The digital serial interface may comprise an audio serial port (ASP).

In some embodiments, the routing circuitry is configurable by the at least one select pin to adjust a multiplexing order of the plurality of output signals in the serial output signal.

In some embodiments, the routing circuitry is configurable by the at least one select pin to adjust an order of extraction of the plurality of input signals from the serial input signal. For example, the input interface may output the plurality of input signals in a different physical order.

The input interface may comprise the plurality of interface pins; and the plurality of data converters may each comprise an analog-to-digital converter (ADC).

Alternatively, the output interface may comprise the plurality of interface pins; and the plurality of data converters may each comprise a digital-to-analog converter (DAC).

The routing circuitry may comprise an analog multiplexer provided between the plurality of interface pins and the plurality of data converters.

The routing circuitry may comprise a digital multiplexer provided between the plurality of data converters and a second one of input interface and the output interface, the second one different from the first one.

In some embodiment, the at least one select pin comprises a single select pin. Such a select pin may be drivable at two or more voltage levels (e.g. ground and Vdd). The routing circuitry may be configurable into two or more routing configurations based on a voltage at the single select pin.

In some embodiment, the at least one select pin comprises a plurality of select pins. The routing circuitry may be configurable into three or more routing configurations based on a combination of voltages at the plurality of select pins.

According to another aspect of the disclosure, there is provided a converter integrated circuit (IC), comprising: an analog input interface comprising a plurality of interface pins, each interface pin configured to receive a respective one of a plurality of analog input signals; an digital output interface for receiving a plurality of digital output signals; a plurality of analog-to-digital converters (ADCs) for converting the plurality of analog input signals into the plurality of digital output signals; and routing circuitry for routing each of the plurality of analog input signals to a respective one of the ADCs or for routing each of the plurality of digital output signals from a respective one of the ADCs to the digital output interface, wherein the routing circuitry is controlled by at least one select pin to adjust the order of routing of the plurality of analog input signals to the ADCs or the plurality of digital output signals from the ADCs.

The digital output interface may comprise a digital serial interface configured to time division multiplex the plurality of digital output signals into a serial digital signal.

According to another aspect of the disclosure, there is provided a converter integrated circuit (IC), comprising: an input interface; an analog output interface comprising a plurality of interface pins, each interface pin configured to output a respective one of a plurality of analog output signals; a plurality of digital-to-analog converters (DACs) for converting the plurality of digital input signals received from the input interface into the plurality of digital output signals; and routing circuitry for routing each of the plurality of digital input signals from the input interface to a respective one of the ADCs or for routing each of the plurality of analog output signals from a respective one of the DACs to the analog output interface, wherein the routing circuitry is controlled by a select pin to adjust the order of routing of the plurality of digital input signals to the DACs or the plurality of analog output signals from the DACs.

The input interface may comprise a digital serial interface configured to convert a received digital serial input signal into the plurality of digital input signals.

According to another aspect of the disclosure, there is provided an integrated circuit (IC) comprising: a plurality of input interfaces for receiving analog input signals; a plurality of data converters assignable to the input interfaces to convert the analog input signals into digital signals; and an output serial interface to output digital signals from the data converters in a multiplexed order, wherein the IC further comprises a hardware pin to selectably configure the IC between at least first and second predefined interface layouts.

The hardware pin may be configured to selectably configure a multiplexing order of the digital output signals based on a voltage at the hardware pin.

The output serial interface may be configured to output digital signals as a time domain multiplexed (TDM) signal.

According to another aspect of the disclosure, there is provided an integrated circuit (IC), comprising: a plurality of input interfaces to receive analog input signals; a plurality of data converters coupled to the input interfaces to convert the analog input signals into digital signals; and an output interface to provide digital output signals based on the digital signals from the data converters, wherein the IC further comprises a hardware pin to select an order of inputs from at least first and second predefined input orders, and to assign the selected input order to the digital output signals.

The converter IC may be a multichannel audio IC for use in a multichannel audio system.

According to another aspect of the disclosure, there is provided an integrated circuit (IC) comprising: a plurality of output interfaces for outputting analog output signals; a plurality of data converters assignable to the output interfaces to convert a plurality of digital input signals into the analog output signals; and an input serial interface to receive a digital input signal and demultiplex the serial digital input signal into the digital input signals, wherein the IC further comprises a hardware pin to selectably configure the IC between at least first and second predefined interface layouts.

According to another aspect of the disclosure, there is provided an integrated circuit (IC), comprising: a plurality of output interfaces to output analog output signals; a plurality of data converters coupled to the output interfaces to convert digital signals into the analog output signals; and an input interface to provide the digital signals to the data converters based on digital input signals, wherein the IC further comprises a hardware pin to select an order of outputs from at least first and second predefined output orders, and to assign the selected output order to the digital input signals.

According to another aspect of the disclosure, there is provided an audio interface, comprising: any one (or more) of the converter ICs described above; an input and/or output connector for coupling with the input interface and/or the output interface of the IC; and a hardware switch or jumper coupled with the at least one select pin of the IC. The audio interface may comprise an audio interface card or an audio interface board.

According to another aspect of the disclosure, there is provided an audio codec integrated circuit (IC), comprising: an audio input interface; an audio output interface, wherein a first one of the audio input interface and the audio output interface comprises a plurality of interface pins, each interface pin configured to receive a respective one of a plurality of audio input signals or output a respective one of a plurality of audio output signals; a plurality of data converters for converting the plurality of audio input signals into the plurality of audio output signals; and routing circuitry for routing the plurality of audio input signals to the data converters and the plurality of audio output signals from the data converters, the routing circuitry configurable by at least one select pin to adjust the order of routing of the plurality of audio input signals to the data converters or the order of routing of the plurality of audio output signals from the data converters.

A second one different from the first one of the audio input interface and the audio output interface may comprise: a digital serial interface configured to multiplex the plurality of audio output signals into a serial audio output signal or to demultiplex a received serial audio input signal into the plurality of audio input signals.

The serial audio output signal or the received serial audio input signal may be encoded using time division multiplexing (TDM).

The time division multiplexing may be synchronous or asynchronous.

The audio input interface may comprise the digital serial interface and the audio input interface may be configured to receive the serial audio input signal.

The audio output interface may comprise the digital serial interface and the audio output interface may be configured to output the serial audio output signal.

The digital serial interface may comprise an audio serial port (ASP). The digital serial interface may implement a protocol such as I2C, Soundwire, or SLIMbus.

The routing circuitry may be configurable by the at least one select pin to adjust a multiplexing order of the plurality of audio output signals in the serial audio output signal or to adjust an order of extraction of the plurality of audio input signals from the serial audio input signal.

The audio codec IC may comprise an audio processor configured to process one or more of the plurality of audio input signals or the plurality of audio output signal to generate respective processed audio input signals or audio output signals.

The audio input interface may comprise the plurality of interface pins; and the plurality of data converters each comprise an analog-to-digital converter (ADC).

The audio output interface may comprise the plurality of interface pins; and the plurality of data converters may each comprise a digital-to-analog converter (DAC).

The routing circuitry may comprise an analog multiplexer provided between the plurality of interface pins and the plurality of data converters.

The routing circuitry may comprise a digital multiplexer provided between the plurality of data converters and a second one of audio input interface and the audio output interface, the second one different from the first one.

The at least one select pin may comprise a single select pin drivable at two or more voltage levels. The routing circuitry may be configurable into two or more routing configurations based on a voltage at the single select pin.

The at least one select pin may comprise a plurality of select pins. The routing circuitry may be configurable into three or more routing configurations based on a combination of voltages at the plurality of select pins.

According to another aspect of the disclosure, there is provided an audio: codec integrated circuit (IC), comprising an analog audio input interface comprising a plurality of interface pins, each interface pin configured to receive a respective one of a plurality of analog audio input signals; a digital audio output interface for receiving a plurality of digital audio output signals; a plurality of analog-to-digital converters (ADCs) for converting the plurality of analog audio input signals into the plurality of digital audio output signals; and routing circuitry for routing each of the plurality of analog audio input signals to a respective one of the ADCs or for routing each of the plurality of digital audio output signals from a respective one of the ADCs to the digital audio output interface, wherein the routing circuitry is controlled by at least one select pin to adjust the order of routing of the plurality of analog audio input signals to the ADCs or the plurality of digital audio output signals from the ADCs.

The digital audio output interface may comprise a digital serial interface configured to time division multiplex the plurality of digital audio output signals into a serial digital audio signal.

According to another aspect of the disclosure, there is provided an audio codec integrated circuit (IC), comprising: an audio input interface; an analog audio output interface comprising a plurality of interface pins, each interface pin configured to output a respective one of a plurality of analog audio output signals; a plurality of digital-to-analog converters (DACs) for converting the plurality of digital audio input signals received from the audio input interface into the plurality of digital audio output signals; and routing circuitry for routing each of the plurality of digital audio input signals from the audio input interface to a respective one of the ADCs or for routing each of the plurality of analog audio output signals from a respective one of the DACs to the analog audio output interface, wherein the routing circuitry is controlled by a select pin to adjust the order of routing of the plurality of digital audio input signals to the DACs or the plurality of analog audio output signals from the DACs.

The audio input interface may comprise a digital serial interface configured to convert a received digital serial audio input signal into the plurality of digital audio input signals.

According to another aspect of the disclosure, there is provided an audio codec integrated circuit (IC) comprising: a plurality of audio input interfaces for receiving analog audio input signals; a plurality of data converters assignable to the audio input interfaces to convert the analog audio input signals into digital audio signals; and an output audio serial interface to output digital audio signals from the data converters in a multiplexed order, wherein the IC further comprises a hardware pin to selectably configure the IC between at least first and second predefined interface layouts.

The hardware pin may be configured to selectably configure a multiplexing order of the digital audio output signals based on a voltage at the hardware pin.

The output audio serial interface may be configured to output digital audio signals as a time domain multiplexed (TDM) signal.

According to another aspect of the disclosure, there is provided an audio codec integrated circuit (IC), comprising: a plurality of audio input interfaces to receive analog audio input signals; a plurality of data converters coupled to the input audio interfaces to convert the analog audio input signals into digital signals; and an audio output interface to provide digital audio output signals based on the digital audio signals from the data converters, wherein the IC further comprises a hardware pin to select an order of audio inputs from at least first and second predefined input orders, and to assign the selected input order to the digital audio output signals.

According to another aspect of the disclosure, there is provided an audio codec integrated circuit (IC), comprising: an audio input interface; an audio output interface, wherein a first one of the audio input interface and the audio output interface comprises a plurality of interface pins, each interface pin configured to receive a respective one of a plurality of audio input signals or output a respective one of a plurality of audio output signals; a plurality of data converters for converting the plurality of audio input signals into the plurality of audio output signals; and routing circuitry for routing the plurality of audio input signals to the data converters and the plurality of audio output signals from the data converters, wherein a second one of the audio input interface and the audio output interface different from the first one comprises a digital serial interface configured to multiplex the plurality of audio output signals into a serial audio output signal or to demultiplex a received serial audio input signal into the plurality of audio input signals, the digital serial interface configurable by at least one select pin to adjust a multiplexing operation of the digital serial interface.

According to another aspect of the disclosure, there is provided a device comprising any of the converter ICs or audio interfaces described above.

The device may comprise a mobile phone, a tablet computer, a laptop, a speaker system, an audio amplifier, an audio mixing desk, an audio card.

The device may be configured for mounting in an audio rack.

According to another aspect of the disclosure, there is provided an audio rack comprising the device described above.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIG. 1 is a schematic diagram of a converter integrated circuit (IC);

FIG. 2 is a timing diagram for a four channel time division multiplexed (TDM) signal;

FIG. 3 illustrates an audio interface comprising the IC of FIG. 1;

FIG. 4 is a routing diagram for the audio interface of FIG. 3;

FIG. 5 is a schematic diagram of a converter IC according to embodiments of the disclosure in a first configuration;

FIG. 6 is schematic diagram of the converter IC of FIG. 5 in a second configuration;

FIGS. 7 to 12 are schematic diagrams of various exemplary circuitry implemented on the converter IC of FIG. 5.

### DESCRIPTION OF EMBODIMENTS

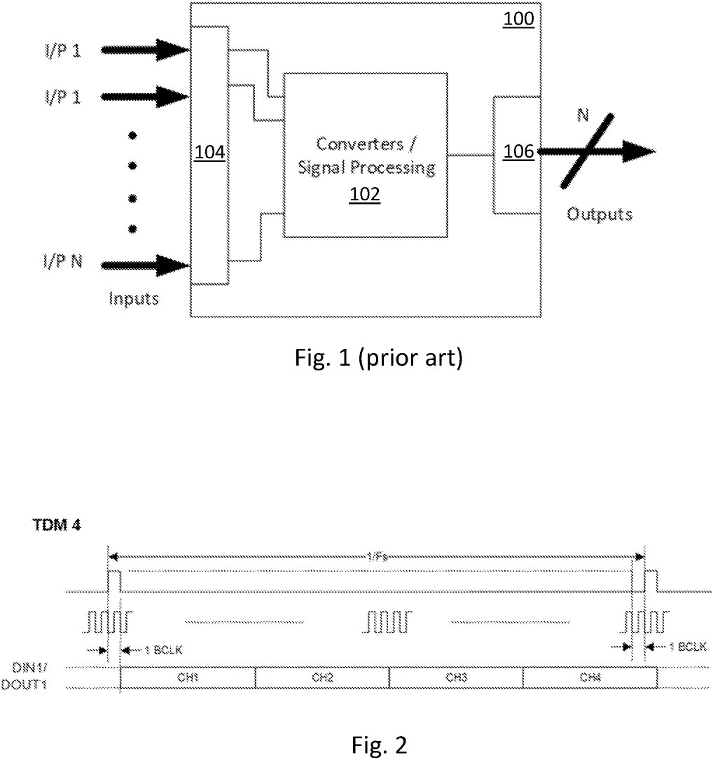

FIG. 1 is a schematic diagram of a converter integrated circuit (IC) 100 comprising converter circuitry 102, an input interface 104 and an output interface 106. The input interface 104 is a parallel input interface configured to receive plurality of inputs I/P1:I/PN. The output interface 106 is a serial output interface configured to output a serial output signal comprising multiple output channels multiplexed, for example in the time domain (time division multiplexed (TDM)).

Whilst, in the embodiment shown, a single serial output signal is output from the output interface, in other embodiments, the output interface 106 may be configured to output more than one serial output signal (i.e. multiple output signals). For example, four output channels may be encoded into a first serial output signal and four output channels may be encoded into a second serial output signal.

In a variation of the embodiment shown in FIG. 1, the parallel input interface 104 may be substituted with a serial interface such as that of the output interface 106. Equally, in other embodiments, the serial output interface 106 may be substituted with a parallel interface, such as the parallel input interface 104.

The converter circuitry 102 may comprise multiple data converters configured to convert a respective input signal into a corresponding output signal. Such converters may comprise analog-to-digital converters (ADCs), digital-to-analog converters (DACs), or a combination of both ADCs and DACs. The converter circuitry 102 may further comprise one or more multiplexers (e.g. TDM) configured to multiplex multiple converted input signals into a serial output signal for output at the output interface 106.

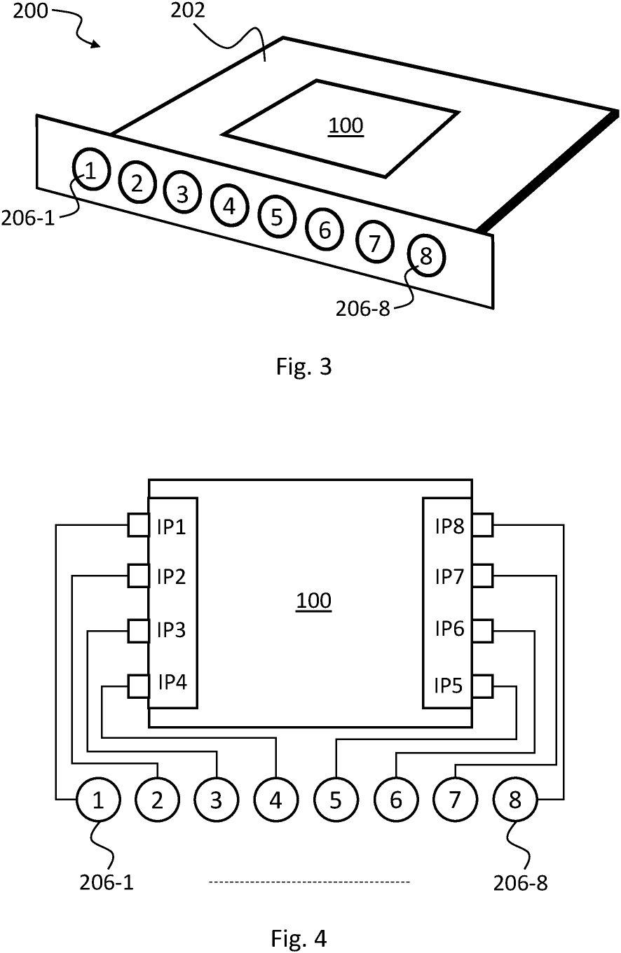

FIG. 2 is a timing diagram of an example 4-channel synchronous TDM signal comprising four channels of data CH1 :CH4, although other channel schemes are known in the art (e.g. 8 or 16 channels). The four data channels CH1:CH4 are encoded sequentially in in the TDM signal over a sampling period ⅟Fs, where Fs is the sample rate.

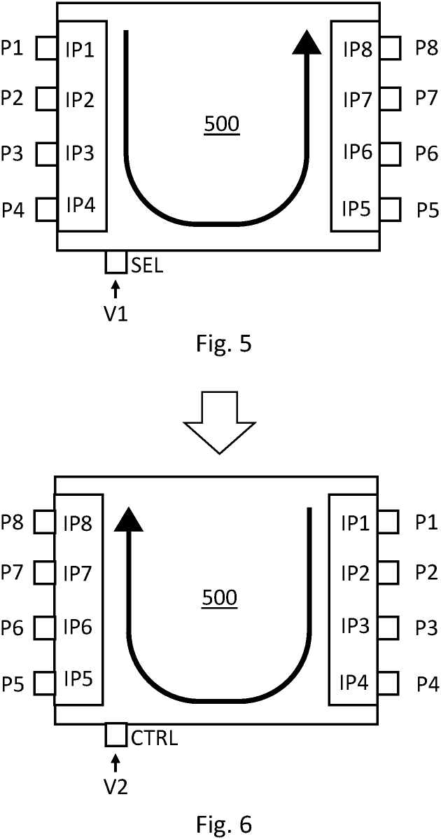

FIG. 3 is a schematic diagram of an audio interface 200 comprising the converter IC 100 of FIG. 1. The audio interface 200 comprises a printed circuit board (PCB) 202 upon which the converter IC 100 is mounted, a face plate 204, and a plurality of input/output (I/O) ports 206–1:206:8 mounted to the face plate 204. Whilst in the embodiment shown, 8 I/O ports 206–1:206:8 are provided, embodiments of the present disclosure are not limited to 8 channels. The audio interface 200 may comprise additional port(s) and/or additional IC(s) (not shown). The I/O ports 206-1:206:8 may be arranged in a linear sequence along an edge of the PCB 202. The audio interface 200 may be rack mountable, meaning that it may be configured to be inserted into an audio rack alongside other audio interfaces. When in place in such an audio rack, the face plate 204 and the I/O ports 206–1:206:8 may be configured to face towards a front (i.e. accessible) side of the audio rack to allow access to the I/O ports. In some embodiments, the face plate 204 may comprise physical labels, denoting the value and/or function of each of the I/O ports 206–1:206:8 to enable a user of the audio interface 200 to distinguish between the I/O ports 206-1:206:8.

Preferably, to allow for spaced routing of signals from the IC 100 to the I/O ports 206-1:206:8, the IC 100 may be designed to have a pinout configuration that avoids overlaps of data paths routed to the I/O ports 206-1:206-8.

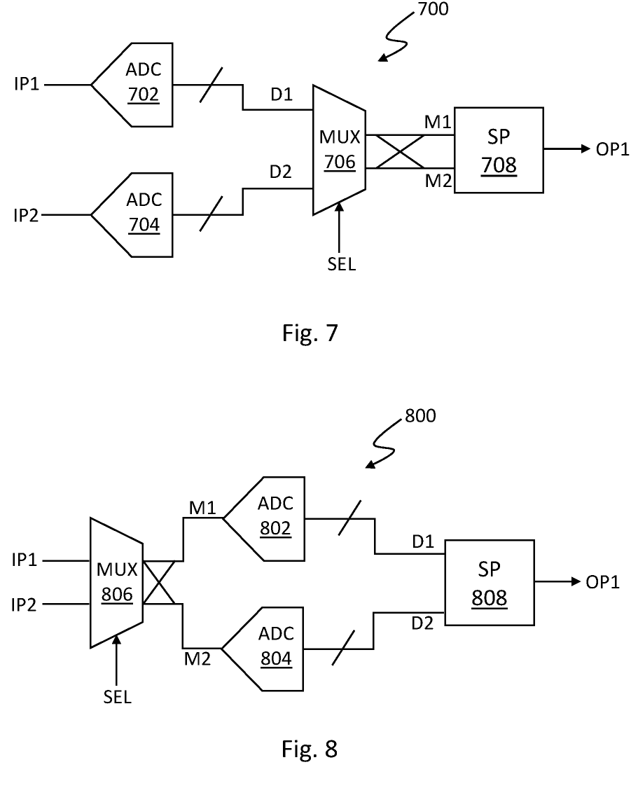

FIG. 4 is a schematic diagram showing an example PCB routing pattern between pins IP1:IP8 of the IC 100 and the I/O ports 206-1:206:8. It can be seen that the arrangement of pins IP1:IP8 enables signals to be routed between the IC 100 and the I/O ports 206-1:206:8 without overlap.

The above approach to design of the IC 100 is satisfactory when the IC 100 is always used in the same orientation, such as being mounted on a top side of the PCB 202. With reference to FIGS. 3 and 4, with the IC 100 mounted on the top side of the PCB 202, the I/O ports 206–1:206:8 will remain sequentially numbered from left to right as shown in FIG. 3.

However, in some circumstances, it may be desirable to use the IC 100 in a different orientation. For example, there may be situations in which it is preferable to mount the IC 100 on an underside of the PCB 202. This may be particularly applicable where multiple ICs are mounted on the top side and underside of the PCB 202. If the IC 100 were to be mounted on the underside of the same PCB 202, routing of signals between the pins IP1:IP8 and the I/O ports 206–1:206:8 would be reversed.

Additionally, in some circumstances, it may be desirable to use the IC 100 for multiple different applications. For example, it may be desirable to allow the IC 100 to be integrated into different types of audio interface. This may be particularly applicable where the IC 100 is manufactured by one party and then provided to one or more third parties for integration into different products. For example, it may be desirable to enable the IC 100 to be integrated either into the audio interface 200 in which the I/O ports 206-1:206-8 are labelled left to right on the face plate 204 or into another audio interface (not shown) having I/O ports labelled in an opposite direction to those of the face plate 204 of the audio interface 200. This may be the applicable for audio interfaces having I/O ports that, in use, face away from the user. In such circumstances, it may be desirable for the order of I/O ports to be reversed relative to the orientation shown in FIG. 3. As such, it may also be desirable to allow a user of the audio interface 200 to change the configuration of I/O ports 206–1:206-8 depending on how the audio interface 200 is being used. For example, where the audio interface 200 is orientated in use such that the face plate 204 faces away from a user, it may be desirable to reverse the order of the I/O ports so that from the perspective of the user, they run from 1 through 8 left to right.

Embodiments of the present disclosure aim to address or ameliorate one or more of the issues discussed above by providing a multi-channel converter IC having a dedicated hardware pin which allows a channel order to be reconfigured. The hardware pin may be set to one of at least two predefined voltages (e.g. ground (GND), a supply voltage (Vdd) etc.). A voltage level on the hardware pin may define a channel order for an input and/or output interface of the IC. Such a voltage level may be set on a PCB upon which the IC may be mounted, for example through routing of the pin to one or more voltage rails, or by using a jumper connection to select the voltage level.

A dedicated hardware pin allows a third party or end-user to easily incorporate an IC into larger multi-channel systems with different routing, mounting and/or port configurations or requirements. Additionally, providing reconfiguration options in hardware (as opposed to software) reduces the complexity and time overhead associated with pin reconfiguration, since an end user need only set a voltage at a pin. This is contrast to software reconfiguration which would require the writing of appropriate layout requirements to internal registers in an IC, such a process being time consuming and onerous on the part of the end-user. Additionally, IC manufacturers may not wish for end users to be given software control of functionality of an IC. By limiting or preventing such software control, the overhead associated with integrating the IC into other products may be reduced. Such limitations may also reduce load on the IC, other components controlling or communicating with the IC, and/or devices into which the IC is integrated.

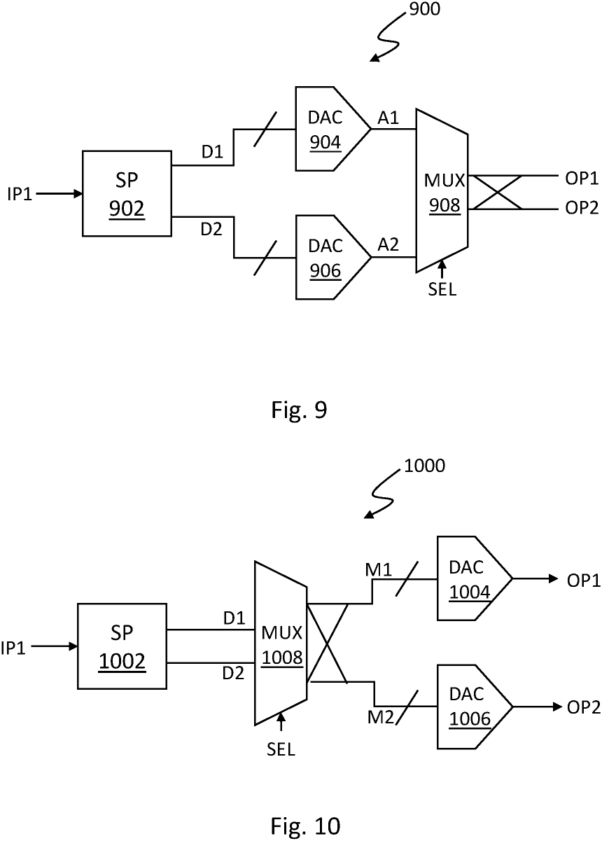

FIG. 5 is a schematic diagram of an exemplary configurable IC 500 according to embodiments of the present disclosure.

The IC 500 may function in a similar manner to the IC 100 described above. As such (like parts being given like numerals), the IC 500 may comprise the converter circuitry 102, the input interface 104 and the output interface 106 shown in FIG. 1. The input interface 104 may be a parallel input interface configured to receive plurality of inputs I/P1:I/PN. The output interface 106 may be a serial output interface configured to output a serial output signal comprising multiple output channels multiplexed, for example in the time domain (time division multiplexed (TDM)). In other embodiments, the parallel input interface 104 may be substituted with a serial interface such as that of the output interface 106. Equally, in other embodiments, the serial output interface 106 may be substituted with a parallel interface, such as the parallel input interface 104.

Again, the converter circuitry 102 may comprise multiple data converters configured to convert a respective input signal into a corresponding output signal. Such converters may comprise analog-to-digital converters (ADCs), digital-to-analog converters (DACs), or a combination of both ADCs and DACs. The converter circuitry 102 may further comprise one or more multiplexers (e.g. TDM) configured to multiplex multiple converted input signals into a serial output signal for output at the output interface 106.

Like the IC 100 described above, the IC 500 comprises a plurality of I/O pins P1:P8. The IC 500 may comprise additional I/O pins (not shown). In other embodiments, the IC 500 may comprise fewer I/O pins than the 8 shown in FIG. 5. In the embodiment shown, the I/O pins P1:P8 shown are pins used for input signals. It will be appreciated that the concepts described herein apply equally for mapping other signals (such as output signals) to pins of the IC 500.

In contrast to the IC 100, the IC 500 further comprises a configuration select pin SEL. The IC 500 is configured to reconfigure mapping of the inputs IP1:IP8 to the pins P1:P8 in dependence on a voltage provided to the select pin SEL.

In the configuration shown in FIG. 5, with the select pin SEL set to a first voltage V1, the inputs IP1:IP8 to the IC 500 are mapped respectively to the plurality of I/O pints P1:P8 such that the first IP1 to eighth IP8 inputs run anticlockwise around the outside of the IC 500 from the first pin P1 to the eighth pin P8. The first voltage V1 may, for example, be ground (GND) or zero volts.

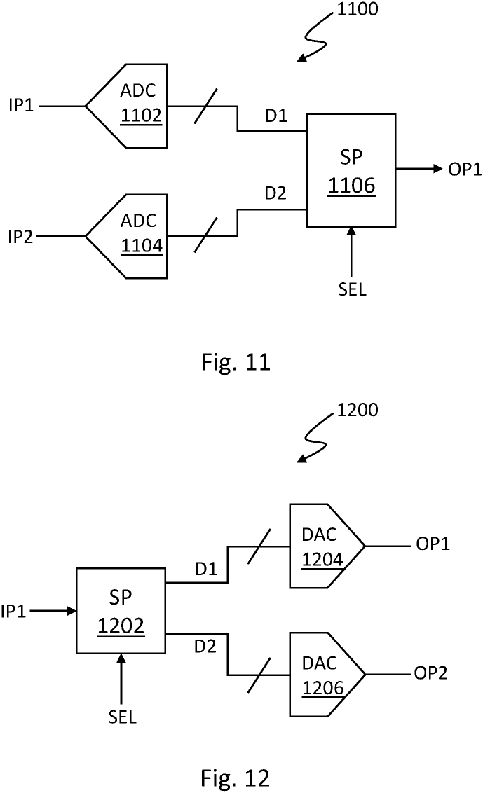

When the select pin SEL is provided with a second voltage V2 different from the first voltage V1, the IC 500 is configured to reconfigure mapping of the inputs IP1:IP8 to the IC 500, as shown in FIG. 6. In the embodiment shown, the inputs IP1:IP8 are reversed such that the first input IP1 is mapped to the eighth P8 and the eighth input IP8 is mapped to the first pin P1. In other words, the first IP1 to eighth IP8 inputs run clockwise around the outside of the IC 500 from the eighth pin P8 to the first pin P1. The second voltage V2 may, for example, be a supply voltage (Vdd) of the IC 500.

As such, the pinouts of the IC 500 may be reconfigured using the select pin SEL without the need for any software intervention.

It will be appreciated that reconfiguration of the IC 500 is not limited to the example shown in FIGS. 5 and 6. In other embodiments, the IC 500 may be reconfigurable between any combination of different pinout configurations. Additionally, whilst in the example shown in FIGS. 5 and 6 show two different configurations (based on two voltages V1, V2), the inputs IP1:IP8 may be reconfigurable into more than two different configurations. Such reconfiguration may be based on more than two different voltages provided to the select pin SEL.

In the embodiments described with reference to FIGS. 5 and 6, the IC 500 is provided with a single select pin SEL. In other embodiments, the IC 500 may be provided with multiple hardware select pins. In such embodiments, a pinout configuration of the IC 500 may depend on a combination of voltages provided to each of the multiple select pins. Such a configuration may enable a large amount of different pinout configurations to be selected using the hardware select pins.

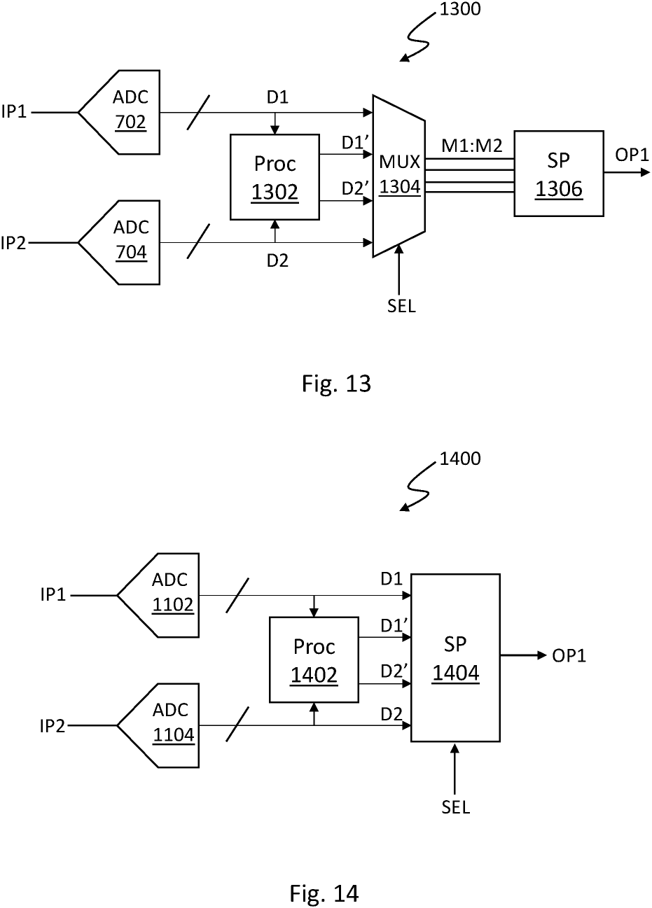

As noted above, the IC 500 may comprise one or more ADCs and/or one or more DACs for converting input signals between the analog and digital domain. FIGS. 7 to 10 show examples of various reconfigurable circuit implementations. For simplicity, such implementations are shown having two channels (either two input channels or two output channels).

FIG. 7 schematically illustrates circuitry 700 for conversion of two analog input signals IP1, IP2 into a digital output signal OP1. The circuitry 700 comprises a first ADC 702, a second ADC 704, a multiplexer (MUX) 706 and a serial port 708.

The first and second input signals IP1, IP2 are provided respectively to the first and second ADCs 702, 704 which are configured to convert each of the first and second input signals IP1, IP2 into respect first and second digital representations D1, D2 of the first and second input signals IP1, IP2. Each of the ADCs 702, 704 may be implemented using any conceivable converter technology.

The first and second digital representations D1, D2 are provided to the MUX 706. The MUX 706 has two outputs M1, M2. In a first configuration, the MUX 706 is configured to output the first digital representation D1 at the first output M1 and the second digital representation D2 at the second output M2. In a second configuration, the MUX 706 is configured to output the first digital representation D1 at the second output M2 and the second digital representation D2 at the first output M1. The configuration of the MUX 706 is configured by a select signal SEL which may be received at, or controlled based on, a voltage provided at the hardware select pin SEL of the IC 500. Thus, the MUX 706 can be configured to swap the output configuration of the first and second digital representations D1, D2.

The first and second outputs M1, M2 of the MUX 706 are provided as inputs to the serial port 708. The serial port 708 is configured to multiplex (e.g., time division multiplex) the received first and second outputs M1, M2 into a serial output signal OP1, such as in the manner described above with reference to FIG. 2.

Thus, by changing the order of inputs of the digital representations D1, D2 into the serial port, the configuration of inputs can also be reordered. For example, if the first and second inputs IP1, IP2 can be switched, the MUX 706 configuration can be changed to obtain the same time multiplexing order in the serial output signal OP1. It will be appreciated that this concept can be scaled to any number of channels by providing additional ADCs, a modified MUX configured to receive additional inputs and output additional outputs and a modified serial port configured to multiplex more than two channels, for example using TDM.

FIG. 8 schematically illustrates circuitry 800 for conversion of two analog input signals IP1, IP2 into a digital TDM output signal OP1. The circuitry 800 comprises a first ADC 802, a second ADC 804, a multiplexer (MUX) 806 and a serial port 808. The circuitry 800 is variation of the circuitry 700 shown in FIG. 7 whereby, instead of providing the MUX 706 to switch the order of the digital representations D1, D2, the MUX 806 is provided to switch the order of the analog input signals IP1, IP2 before conversion into the digital domain.

The first and second input signals IP1, IP2 are provided to the MUX 706. The MUX 706 has two outputs M1, M2. In a first configuration, the MUX 706 is configured to output the first input signal IP1 at the first output M1 and the second input signal IP2 at the second output M2. In a second configuration, the MUX 706 is configured to output the first input signal IP1 at the second output M2 and the second input signal IP2 at the first output M1. The configuration of the MUX 706 is configured by a select signal SEL which may be received at, or controlled based on, a voltage provided at the hardware select pin SEL of the IC 500.

The first and second outputs M1, M2 are respectively provided to the first and second ADCs 802, 804 which are configured to convert each of the first and second output signals M1, M2 into respect first and second digital representations D1, D2 of the first and second input signals IP1, IP2. Each of the ADCs 802, 804 may be implemented using any conceivable converter technology.

The first and second digital representations D1, D2 are provided as inputs to the serial port 808. The serial port 808 is configured to time domain multiplex the received first and second digital representations D1, D2 into a PDM output signal OP1, in such a manner as that described above with reference to FIG. 2. Thus, by changing the order of inputs of the input signal IP1, IP2 into the respective ADCs 802, 804, the order of multiplexing of the first and second input signals IP1, IP2 into the TDM output signal OP1.

The serial ports 708, 808 may be configured to multiplex the first and second output signals M1, M2 and digital representations D1, D2 respectively, using any conceivable serialisation protocol. For example, the serial ports 708, 808 may be configured to implement time division multiplexing (TDM). In some embodiments, the serial ports 708, 808 may implement synchronous TDM, for example using protocols such as 12C. In some embodiments, the serial ports 708, 808 may implement asynchronous TDM, for example using protocols such as serial low-power inter-chip media bus (SLIMbus) or SoundWire.

FIGS. 7 and 8 illustrated circuitry for converting multiple analog input signals into a digital TDM output signal. In some embodiments, however, the IC 500 may be implemented with converter circuitry for converting a received serial digital signal into multiple analog output signals.

FIG. 9 is a schematic diagram of circuitry 900 for converting a two-channel serial digital input signal IP1 into two analog output signals OP1, OP2. The circuitry 900 comprises a serial port 902, first and second digital to analog converters (DACs) 904, 906, and a multiplexer (MUX) 908.

The serial digital signal IP1 is received by the serial port 902 which converts (e.g., demultiplexes) the input signal IP1 into first and second digital representations D1, D2 representing first and second channels of the digital TDM signal IP1.

The first and second digital representations D1, D2 are provided respectively to first and second DACs 904, 906. Each DAC 904, 906 is configured to convert one of the first and second digital representations D1, D2 into one of first and second analog signal A1, A2.

The analog signals A1, A2 are then provided to the MUX 908. The MUX 908 is configured to output two analog output signal OP1, OP2. In a first configuration, the MUX 908 is configured to output the first analog signal A1 as the first output signal OP1 and the second analog signal A2 at the second output signal OP2. In a second configuration, the MUX 908 is configured to output the first analog signal A1 at the second output M2 and the second analog signal A2 at the first output M1. The configuration of the MUX 908 is configured by a select signal SEL which may be received at, or controlled based on, a voltage provided at the hardware select pin SEL of the IC 500.

FIG. 10 is a schematic diagram of circuitry 1000 which is a variation of the circuitry 900 of FIG. 9. The circuitry 1000 comprises a serial port 1002, first and second DACs 1004, 1006 and a multiplexer (MUX) 1008. The circuitry is configured to convert a two-channel serial digital input signal IP1 into two analog output signals OP1, OP2.

The two-channel serial digital input signal IP1 is received by the serial port 902 which converts (e.g., demultiplexes) the digital input signal IP1 into first and second digital representations D1, D2 representing first and second channels of the digital input signal IP1.

The first and second digital representations D1, D2 are provided to the MUX 1008. The MUX 1008 has two outputs M1, M2. In a first configuration, the MUX 1008 is configured to output the first digital representation D1 at the first output M1 and the second digital representation D2 at the second output M2. In a second configuration, the MUX 1008 is configured to output the first digital representation D1 at the second output M2 and the second digital representation D2 at the first output M1. The configuration of the MUX 1008 is configured by a select signal SEL which may be received at, or controlled based on, a voltage provided at the hardware select pin SEL of the IC 500. Thus, the MUX 1008 can be configured to swap the output configuration of the first and second digital representations D1, D2.

The two outputs M1, M2 of the MUX 1008 are provided to the first and second DACs 1004, 1006 respectively to be converted into first and second analog output signal OP1, OP2.

The serial ports 902, 1002 may be configured to demultiplex respective digital input signals IP1, using any suitable deserialization protocol. In some embodiments, the serial ports 902, 1002 may implement synchronous TDM, for example using protocols such as 12C. In some embodiments, the serial ports 902, 1002 may implement asynchronous TDM, for example using protocols such as serial low-power inter-chip media bus (SLIMbus) or SoundWire.

In the embodiments described above with reference to FIGS. 7 to 10, reordering of various signals is performed either after a digital input signal has been converted back into a plurality of separate channels of data, or before separate channels of data are encoded into a single digital output signal. In other embodiments, however, reconfiguration may be performed by a serial port itself.

FIG. 11 is a schematic diagram of circuitry 1100 for converting multiple analog input signals IP1, IP2 into a serial digital output signal OP1. For simplicity, a two-channel embodiment is shown but it in practice any number of channels may be implemented. The circuitry 1100 comprises first and second ADCs 1102, 1104 and a configurable serial port 1106.

First and second input signals IP1, IP2 are provided to respective first and second ADCs 1102, 1104 which are configured to generate respective first and second digital representation D1, D2 of the first and second input signals IP1, IP2. These first and second digital representations D1, D2 are provided to the configurable serial port 1106 which is configured to multiplex the first and second digital representations D1, D2 into a serial output signal OP1. In some embodiments, such multiplexing may be time division multiplexing (TDM). In some embodiments, synchronous TDM may be implemented, for example using protocols such as 12C. In some embodiments, asynchronous TDM may be implemented, for example using protocols such as serial low-power inter-chip media bus (SLIMbus) or SoundWire.

The configurable serial port 1106 may be configurable by a select signal SEL to change the order in which the first and second digital representations D1, D2 are multiplexed into the serial output signal OP1. The select signal SEL which may be received at, or controlled based on, a voltage provided at the hardware select pin SEL of the IC 500.

As such, if the inputs IP1, IP2 are reordered, the hardware select pin SEL can be controlled to reorder the order of multiplexing of the first and second digital representations D1, D2 so that the serial output signal OP1 remains the same.

In some embodiments, the serial port 1106 implement an asynchronous TDM protocol to multiplex the first and second digital representations D1, D2. For example, the serial port 1106 may be configured to generate audio packets with channel data pertaining to the first and second digital representations D1, D2, as part of a packet header provided with a respective audio packet. The hardware select pin SEL may be controlled to determine the channel data to be written to the packet header of the respective audio packet. For example, depending on the selection of the select pin SEL, data pertaining to the first and second digital representations D1, D2 may be written to different audio packet headers for output as the serial output signal OP1.

FIG. 12 is a schematic diagram of circuity 1200 for converting a digital input signal into multiple analog output signals. For simplicity, a two-channel embodiment is shown. The circuitry 1200 comprises a configurable serial port 1202 and first and second ADCs 1102, 1104.

A two-channel serial digital signal IP1 is received by the serial port 1202 which converts the digital signal IP1 into first and second digital representations D1, D2 representing first and second channels of the digital signal IP1.

Like the configurable serial port 1106, the configurable serial port 1202 may be configurable by a select signal SEL to change the order in which demultiplexed first and second digital representations D1, D2 from the digital input signal IP1 are provided as the first and second digital representations D1, D2. In one configuration, the first received channel (in time) is demultiplexed as the first digital representation D1 and the second received channel (in time) is demultiplexed as the second digital representation D2. In another configuration, the first received channel (in time) is demultiplexed as the second digital representation D2 and the second received channel (in time) is demultiplexed as the first digital representation D1. The select signal SEL which may be received at, or controlled based on, a voltage provided at the hardware select pin SEL of the IC 500.

In a variation of the embodiments described above, circuitry may be provided to generate processed versions of received audio signals. Such processed versions of received audio signals may be provided as outputs in addition to or as alternatives to the received audio signals. The order of output of these received audio signals may be adjusted, in addition to, or alternatively to, the order of output of the received audio signals. In one example, circuitry may receive an audio signal from a musical instrument (e.g., guitar) and generate a reverb version of the received audio signal. A hardware pin can be controlled to re-order the output order of the original version of the received audio signal and the processed version of the received audio signal.

FIG. 13 is a schematic diagram of circuitry 1300 which is a variation of the circuitry 700 of FIG. 7, like parts given like numbering. The first and second digital representations D1, D2 are provided to an audio processor 1302 which is configured to generate respect first and second processed digital representations D1′, D2′ of respective first and second digital representations D1, D2. The audio processor 1302 may be configured to perform one or more processing functions. Any conceivable processing function may be implemented by the audio processor 1302. For example, the audio processor 1302 may be configured to apply one or more effects to the first and/or second digital representations D1, D2, such as reverb, distortion, compression, modulation, chorus, flange etc.

Each of the first and second digital representations D1, D2 and the first and second processed digital representations D1′, D2′ may then be provided to a multiplexer (MUX) 1304 which may be configured to change the order of output of respective first, second, third and fourth signals M1, M2, M3, M4 to a serial port 1306. The serial port 1306 may function in a similar manner to the serial port 708, multiplexing the received first, second, third and fourth signals M1, M2, M3, M4 into a serial output signal SP1. Thus, the circuitry 1300 is configured to reorder the output of both the first and second digital representations D1, D2 and the first and second processed digital representations D1′, D2′. The multiplexer 1304 may be configurable by the select pin SEL to output any combination of the first and second digital representations D1, D2 and the first and second processed digital representations D1′, D2′. For example. The multiplexer 1304 may be configured to output only the first and second processed digital representations D1′, D2′ and not output the first and second digital representations D1, D2.

FIG. 14 is a schematic diagram of circuitry 1400 which is a variation of the circuitry 1100 of FIG. 11, like parts given like numbering. The first and second digital representations D1, D2 are provided to an audio processor 1402 (similar to the audio processor 1302 of FIG. 13). The audio processor 1402 is configured to generate respect first and second processed digital representations D1′, D2′ of respective first and second digital representations D1, D2. The first and second digital representations D1′, D2′ and the first and second digital representations D1, D2 are provided to a configurable serial port 1404 similar to the serial port 1106 of FIG. 14. The configurable serial port 1404 may be configurable by a select signal SEL to change the order in which the first and second digital representations D1, D2 and the first and second digital representations D1′, D2′ are multiplexed into a serial output signal OP1. The configurable serial port may also be configured to output any combination of the first and second digital representations D1, D2 and the first and second digital representations D1′, D2′ in the serial output signal OP1. Such confirmation may be controlled by a select signal SEL.

In the embodiments described with reference to FIGS. 13 and 14 above, audio processing by the respective audio processors 1302, 1402 is performed in the digital domain. It will, however, be appreciated that such processing could equally be performed in the analog domain without departing from the scope of the present disclosure. It will also be appreciated that the embodiments shown in FIGS. 8, 9, 10 and 12 could be modified in a similar manner to that described above with reference to FIGS. 7 and 11 to incorporate circuitry (e.g., audio processors) for processing one or more signals (digital or analog) for output as the various output signals described (digital or analog).

As mentioned above, it will be understood that the examples described herein, such as those described with reference to FIGS. 8 to 14, may be extended to ICs having greater than two channels.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote control device, a home automation controller or a domestic appliance including a domestic temperature or lighting control system, a toy, a machine such as a robot, an audio player, a video player, or a mobile telephone for example a smartphone.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. An audio codec integrated circuit (IC), comprising:
an audio input interface;
an audio output interface, wherein a first one of the audio input interface and the audio output interface comprises a plurality of interface pins, each interface pin configured to receive a respective one of a plurality of audio input signals or output a respective one of a plurality of audio output signals;
a plurality of data converters for converting the plurality of audio input signals into the plurality of audio output signals; and
routing circuitry for routing the plurality of audio input signals to the data converters and the plurality of audio output signals from the data converters, the routing circuitry configurable by at least one select pin to adjust the order of routing of the plurality of audio input signals to the data converters or the order of routing of the plurality of audio output signals from the data converters.

2. The audio codec IC of claim 1, wherein a second one different from the first one of the audio input interface and the audio output interface comprises:
a digital serial interface configured to multiplex the plurality of audio output signals into a serial audio output signal or to demultiplex a received serial audio input signal into the plurality of audio input signals.

3. The audio codec IC of claim 2, wherein the serial audio output signal or the received serial audio input signal are encoded using time division multiplexing (TDM).

4. The Audio codec IC of claim 3, wherein the time division multiplexing is synchronous or asynchronous.

5. The audio codec IC of claim 2, wherein the audio input interface comprises the digital serial interface, wherein the audio input interface is configured to receive the serial audio input signal.

6. The audio codec IC of claim 2, wherein the audio output interface comprises the digital serial interface, wherein the audio output interface is configured to output the serial audio output signal.

7. The audio codec IC of claim 2, wherein the digital serial interface comprises an audio serial port (ASP).

8. The audio codec IC of claim 2, wherein the routing circuitry is configurable by the at least one select pin to adjust a multiplexing order of the plurality of audio output signals in the serial audio output signal or to adjust an order of extraction of the plurality of audio input signals from the serial audio input signal.

9. The audio codec IC of claim 2, further comprising an audio processor configured to process one or more of the plurality of audio input signals or the plurality of audio output signal to generate respective processed audio input signals or audio output signals.

10. The audio codec IC of claim 1, wherein:
the audio input interface comprises the plurality of interface pins; and
the plurality of data converters each comprise an analog-to-digital converter (ADC).

11. The audio codec IC of claim 1, wherein:
the audio output interface comprises the plurality of interface pins; and
the plurality of data converters each comprise a digital-to-analog converter (DAC).

12. The audio codec IC of claim 1, wherein the routing circuitry comprises an analog multiplexer provided between the plurality of interface pins and the plurality of data converters.

13. The audio codec IC of claim 1, wherein the routing circuitry comprises a digital multiplexer provided between the plurality of data converters and a second one of audio input interface and the audio output interface, the second one different from the first one.

14. The audio codec IC of claim 1, wherein the at least one select pin comprises a single select pin drivable at two or more voltage levels, the routing circuitry configurable into two or more routing configurations based on a voltage at the single select pin.

15. The audio codec IC of claim 1, wherein the at least one select pin comprises a plurality of select pins, the routing circuitry configurable into three or more routing configurations based on a combination of voltages at the plurality of select pins.

16. An audio codec integrated circuit (IC), comprising:
an analog audio input interface comprising a plurality of interface pins, each interface pin configured to receive a respective one of a plurality of analog audio input signals;
an digital audio output interface for receiving a plurality of digital audio output signals;
a plurality of analog-to-digital converters (ADCs) for converting the plurality of analog audio input signals into the plurality of digital audio output signals; and
routing circuitry for routing each of the plurality of analog audio input signals to a respective one of the ADCs or for routing each of the plurality of digital audio output signals from a respective one of the ADCs to the digital audio output interface,
wherein the routing circuitry is controlled by at least one select pin to adjust the order of routing of the plurality of analog audio input signals to the ADCs or the plurality of digital audio output signals from the ADCs.

17. The audio codec IC of claim 16 wherein the digital audio output interface comprises a digital serial interface configured to time division multiplex the plurality of digital audio output signals into a serial digital audio signal.

18. An audio codec integrated circuit (IC), comprising:
an audio input interface;
an analog audio output interface comprising a plurality of interface pins, each interface pin configured to output a respective one of a plurality of analog audio output signals;
a plurality of digital-to-analog converters (DACs) for converting the plurality of digital audio input signals received from the audio input interface into the plurality of digital audio output signals; and
routing circuitry for routing each of the plurality of digital audio input signals from the audio input interface to a respective one of the ADCs or for routing each of the plurality of analog audio output signals from a respective one of the DACs to the analog audio output interface,
wherein the routing circuitry is controlled by a select pin to adjust the order of routing of the plurality of digital audio input signals to the DACs or the plurality of analog audio output signals from the DACs.

19. The audio codec IC of claim 18, wherein the audio input interface comprises a digital serial interface configured to convert a received digital serial audio input signal into the plurality of digital audio input signals.

20. An audio codec integrated circuit (IC) comprising:
a plurality of audio input interfaces for receiving analog audio input signals;
a plurality of data converters assignable to the audio input interfaces to convert the analog audio input signals into digital audio signals; and
an output audio serial interface to output digital audio signals from the data converters in a multiplexed order,
wherein the IC further comprises a hardware pin to selectably configure the IC between at least first and second predefined interface layouts.

21. The audio codec IC of claim 20, wherein the hardware pin is configured to selectably configure a multiplexing order of the digital audio output signals based on a voltage at the hardware pin.

22. The audio codec IC of claim 20, wherein the output audio serial interface is configured to output digital audio signals as a time domain multiplexed (TDM) signal.

23. An audio codec integrated circuit (IC), comprising:
a plurality of audio input interfaces to receive analog audio input signals;
a plurality of data converters coupled to the input audio interfaces to convert the analog audio input signals into digital signals; and
an audio output interface to provide digital audio output signals based on the digital audio signals from the data converters,
wherein the IC further comprises a hardware pin to select an order of audio inputs from at least first and second predefined input orders, and to assign the selected input order to the digital audio output signals.

24. An audio codec integrated circuit (IC), comprising:
an audio input interface;
an audio output interface, wherein a first one of the audio input interface and the audio output interface comprises a plurality of interface pins, each interface pin configured to receive a respective one of a plurality of audio input signals or output a respective one of a plurality of audio output signals;
a plurality of data converters for converting the plurality of audio input signals into the plurality of audio output signals; and
routing circuitry for routing the plurality of audio input signals to the data converters and the plurality of audio output signals from the data converters,
wherein a second one of the audio input interface and the audio output interface different from the first one comprises a digital serial interface configured to multiplex the plurality of audio output signals into a serial audio output signal or to demultiplex a received serial audio input signal into the plurality of audio input signals, the digital serial interface configurable by at least one select pin to adjust a multiplexing operation of the digital serial interface.

25. A device comprising the audio codec IC of claim 24.

26. The device of claim 25, wherein the device comprises an audio interface, the audio interface comprising:
the audio codec IC;
an input and/or output connector for coupling with the audio input interface and/or the audio output interface of the IC; and
a hardware switch or jumper coupled with the at least one select pin of the IC.

27. The device of claim 25, wherein the device comprises a mobile phone, a tablet computer, a laptop, a speaker system, an audio amplifier, an audio mixing desk, an audio card.

28. The device of claim 25, wherein the device is configured for mounting in an audio rack.

29. A device comprising the audio codec IC of claim 1.

30. The device of claim 29, wherein the device comprises an audio interface, the audio interface comprising:
the audio codec IC;
an input and/or output connector for coupling with the audio input interface and/or the audio output interface of the IC; and
a hardware switch or jumper coupled with the at least one select pin of the IC.

31. The device of claim 29, wherein the device comprises a mobile phone, a tablet computer, a laptop, a speaker system, an audio amplifier, an audio mixing desk, an audio card.

32. The device of claim 29, wherein the device is configured for mounting in an audio rack.
